(19) United States
(12) Patent Application Publication
(10) Pub. No.: US 2026/0176740 A1
(43) Pub. Date: Jun. 25, 2026

(54) METHOD OF USING A TLE SYSTEM AND TLE SYSTEM

(71) Applicant: Max-Planck-Gesellschaft zur Förderung der Wissenschaften e.V., München (DE)

(72) Inventors: Wolfgang Braun, Bietigheim-Bissingen (DE); Jochen Mannhart, Böblingen (DE)

(21) Appl. No.: 19/128,873

(22) PCT Filed: Nov. 24, 2022
(86) PCT No.: PCT/EP2022/083168

§ 371 Date: May 9, 2025

(51) Int. Cl. C23C 14/28; C23C 14/54

(52) U.S. Cl. CPC C23C 14/28; C23C 14/54

(57) ABSTRACT

The invention relates to a method of using a thermal laser evaporation (TLE) system. The TLE system comprising a reaction chamber fillable with a reaction atmosphere, a substrate arranged in the reaction chamber, and one or more sources arranged in the reaction chamber. Each source comprising a source element including a source material, and a laser source for providing a laser beam impinging on the source element and thereby evaporating or sublimating the source material for providing a flux of evaporated or sublimated source material for a deposition onto the substrate.

The invention relates to a method of using a thermal laser evaporation (TLE) system, the TLE system comprising a reaction chamber fillable with a reaction atmosphere, a substrate arranged in the reaction chamber, one or more sources arranged in the reaction chamber, each source comprising a source element consisting of a source material, and a laser source for providing a laser beam impinging on the source element and thereby evaporating or sublimating the source material for providing a flux of evaporated or sublimated source material for a deposition onto the substrate. Further, the invention relates to a respective TLE system, the TLE system comprising a reaction chamber fillable with a reaction atmosphere, a substrate arranged in the reaction chamber, one or more sources arranged in the reaction chamber, each source comprising a source element consisting of a source material, and a laser source for providing a laser beam impinging on the source element and thereby evaporating or sublimating the source material for providing a flux of evaporated or sublimated source material for a deposition onto the substrate.

In thermal laser evaporation (TLE), source material is evaporated and/or sublimated in a controlled environment, in particular in a reaction chamber filled with a reaction atmosphere, by means of laser heating, usually with the intent to coat a substrate likewise arranged in the reaction chamber. In other words, coating the substrate is provided by a deposition of a flux of evaporated and/or sublimated source material onto a surface of the substrate.

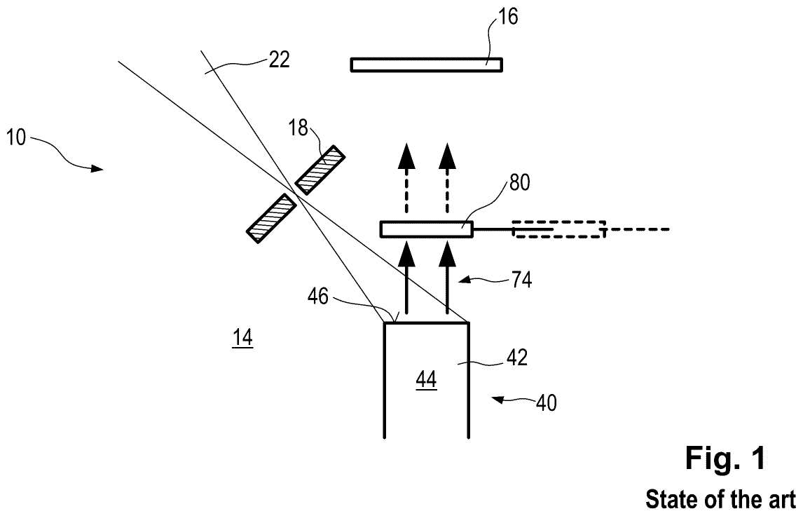

As depicted in FIG. 1, it is known in TLE systems 10 of the state of the art to use mechanically operated shutters 80 for actively blocking and releasing said deposition flux 74 for a modulation of the coating of the substrate 16. Source material 44 of a source element 42 of a source 40 is evaporated and/or sublimated by a laser beam 22 impinging on the source element 42, whereby in the depicted embodiment the laser beam 22 is further constrained by an aperture 18. The shutter 80 does not block the laser beam 22, so a constant deposition flux 74 of evaporated and/or sublimated source material 44 can be established.

However, shutters are always an additional piece of equipment within the reaction chamber and especially exposed to the reaction atmosphere, which covers different variants including ultra-high vacuum or corrosive gases. Often very high temperatures, sometimes exceeding 3500° C., act on the shutters, as especially in TLE systems working distances between source and substrate are short. Likewise, due to the short distances, interactions between material of the shutter and evaporated and/or sublimated source material are possible, leading to impurities in the coating and/or to a failure of the shutter. If more than one source and hence more than one source material are present in the reaction chamber, also contamination between different sources are possible due to evaporated and/or sublimated source material of one source reflected on the shutter towards another source.

In view of the above, it is an object of the present invention to provide an improved method of using a thermal laser evaporation system and an improved thermal laser evaporation system which do not have the aforementioned drawbacks of the state of the art. In particular, it is an object of the present invention to provide an improved method of using a thermal laser evaporation system and an improved thermal laser evaporation system which are enabled to provide a flux of evaporated and/or sublimated source material that can be adjusted, in particular turned on and off, in a controlled and arbitrary manner, in particular that provide a flux of evaporated and/or sublimated source material that rises to a desired flux level immediately or at least after a short time, and/or that decreases to a desired flux level immediately or at least after a short time.

This object is satisfied by the respective independent patent claims. In particular, this object is satisfied by a method of using a thermal laser evaporation system according to independent claim 1 and by a thermal laser evaporation system according to independent claim 22. The dependent claims describe preferred embodiments of the invention. Details and advantages described with respect to a method according to the first aspect of the invention also refer to a thermal laser evaporation system according to the second aspect of the invention, and vice versa, if of technical sense.

In the following, the terms “power” and “intensity” of a laser beam are used as synonyms, since intensity represents power per area and, in the present application, an area on which the incident laser beam impinges is not, or at least not significantly, relevant.

According to the first aspect of the invention, the object is satisfied by a method of using a thermal laser evaporation (TLE) system, the TLE system comprising a reaction chamber fillable with a reaction atmosphere, a substrate arranged in the reaction chamber, one or more sources arranged in the reaction chamber, each source comprising a source element consisting of a source material, and a laser source for providing a laser beam impinging on the source element and thereby evaporating or sublimating the source material for providing a flux of evaporated or sublimated source material for a deposition onto the substrate.

The method according to the present invention comprises the steps of
a) Determining a desired flux of source material evaporated and/or sublimated source material by the laser beam,
b) Determining a nominal heat energy stored in the source element corresponding to the desired flux,
c) Determining a nominal intensity of the laser beam corresponding to the desired flux when the source element stores the nominal heat energy,
d) Determining an actual heat energy stored in the source element,
e) Determining a working intensity of the laser beam in dependence of a deviation of the actual heat energy from the nominal heat energy, wherein
   the working intensity is higher than the nominal intensity if the actual heat energy is smaller than the nominal heat energy, and
   the working intensity is smaller than the nominal intensity if the actual heat energy is higher than the nominal heat energy, and
f) Providing the laser beam with the working intensity.

The method according to the first aspect of the present invention is intended for the usage of a thermal laser evaporation system, or short of a TLE system. In particular, the scope of the present invention is a TLE system in which the laser is used for evaporating or sublimating a source material. Such systems are known in general. A laser beam provided by a laser source is used for evaporating or sublimating the source material, in most of the cases for a deposition of the evaporated or sublimated source material onto a substrate provided as target. The source material is provided as source element arranged in a source within the reaction chamber, wherein one or more sources are possible, in particular providing the same and/or different source materials. The laser beam impinges onto a surface, in most of the cases a top surface, of the source element, providing a flux of evaporated or sublimated source material.

The source is arranged within a reaction chamber, which is sealable against ambient atmosphere and fillable with a reaction atmosphere. Said reaction atmosphere can be vacuum, in particular as low as 10⁻¹² hPa or even lower, or comprise reaction gases at pressures suitable for the material to be deposited, for instance a reaction gas providing oxygen for a deposition of an oxide of evaporated and/or sublimated elemental or compound source material. Maximum values tested with a working distance of 60 mm so far are as high as 10⁻² hPa. Still higher values are likely possible as deposition was possible without problems at 10⁻² hPa.

In most of the cases, at least the main part of the laser source is arranged outside of the reaction chamber and the laser beam is coupled into the reaction chamber via coupling means. Said coupling means can be for instance simple windows in a chamber wall of the reaction chamber. However, coupling means according to the present invention can also comprise adaptive optics for forming the laser beam impinging on the surface of the source element.

By the method according to the present invention, a possibility of turning on and off a provided flux of evaporated and/or sublimated source material in a controlled and arbitrary manner can be provided. In TLE systems according to the state of the art, the laser beam provided by the laser source can be switched on and off with rise times of microseconds, and hence with respect to the flight times of the evaporated and/or sublimated particles essentially immediately, even if laser sources providing laser beams with a power of 1 to 10 kW or more are used. Also changes of the power of the provided laser beam during operation can be realized that fast.

In addition, it has turned out that the actually provided flux strongly depends on said laser power. Experimental data give an approximately Arrhenius-type dependence of flux vs. laser power. In other words, the flux decreases exponentially with the inverse of the laser power. For instance for AI, changing the laser power, e.g., from 200 W to 2000 W by a factor of ten, one obtains a change in flux of approximately three orders of magnitude (a factor of 1000), ranging from growth rates of a few Å to several thousand Å. The method according to the present invention exploits and is based on these findings.

In a first step a) of the method according to the present invention, the main goal of the usage of the TLE system is defined, namely the desired flux of evaporated and/or sublimated source material which should be provided. The desired flux can be for instance a flux of evaporated and/or sublimated source material needed for a certain coating of a substrate likewise arranged in the reaction chamber. In other words, said desired flux should be provided within the respective TLE system.

Due to the given vapor pressure of the source material, the flux of evaporated and/or sublimated source material depends approximately exponentially on the temperature of the source element, more precisely on the surface temperature of the source element. Hence, said surface temperature and the flux of evaporated and/or sublimated source material emitted from said surface are linked. The impinging laser beam is used for changing said temperature, and hence effectively changing the provided flux of evaporated and/or sublimated source material.

However, a non-negligible part of the energy of the impinging laser beam is stored as heat energy in the source element. This happens as long as the entire source element reaches a thermal equilibrium, in which the incoming energy provided by the laser beam equals all outgoing energy losses including the evaporated and/or sublimated source material, but additionally also for instance radiation losses. In other words, as long as this equilibrium is not reached, the temperature of the bulk of the source element rises, also causing a rise of the temperature at the surface of the source element. Due to the aforementioned linkage between surface temperature and provided flux of evaporated and/or sublimated source material, also the provided flux rises till said thermal equilibrium is reached.

It is pointed out that even in the steady state of the thermal equilibrium, there is in most of the cases no uniform temperature in the bulk or at the surface of the source element. Due to the efficient heat losses via radiation, there are always very strong temperature gradients along the surface and throughout the bulk. At steady state, however, these gradients are time invariant. This means they have a strong spatial, but no temporal variation.

In the following step b) of the method according to the present invention, a nominal heat energy stored in the source element is determined, wherein the nominal heat energy corresponds to the desired flux. A heat energy “corresponding to the desired flux” in the sense of the present invention is a heat energy stored in the source element when the aforementioned thermal equilibrium is reached.

Hence, with the source element storing the nominal heat energy, the temperature of the surface is essentially constant and a stable provision of the desired flux can be ensured by simply providing a laser beam with a suitable intensity.

Said intensity of the laser beam needed after reaching the thermal equilibrium is determined in the next step c) of the method according to the present invention by determining the nominal intensity of the laser beam. In other words, if the source element stores the nominal heat energy, a laser beam impinging on the source element with the nominal intensity leads to the desired flux of evaporated and/or sublimated material.

However, the aforementioned thermal equilibrium is not established for all times during evaporation and/or sublimation of source material in the TLE system. In particular after a change in the desired flux, especially at the beginning of the evaporation and/or sublimation process, said equilibrium is far from reached and the heat energy actually stored in the source element differs from the nominal heat energy. Said actually stored heat energy of the source element is determined in step d) of the method according to the present invention as actual heat energy. In other words, after step d) of the method according to the present invention information is at hand during the evaporation and/or sublimation process of the actual value of heat energy stored in the source element.

All this information determined in steps a) to d) of the method according to the present invention is used in the following step e) for determining a working intensity of the laser beam. Said working intensity is determined in dependence of a deviation of the actual heat energy and the nominal heat energy. In other words, it is determined whether, and if applicable how much, the actual heat energy differs from the nominal heat energy.

If the actual heat energy is smaller than the nominal heat energy, the aforementioned thermal equilibrium is not yet reached. In other words, the median temperature of the bulk of the source element is smaller than the surface temperature of the source element needed for an evaporation and/or sublimation of source material with the desired flux. In particular, by the dependence of the working intensity on said deviation of the actual heat energy and the nominal heat energy it is taken into account how much of the impinging laser energy will be used rather for heating up the bulk of the source element than for actually evaporating and/or sublimating source material. Hence, the working intensity is determined higher than the nominal intensity for at least partly compensating the energy of the laser used for said heating up of the bulk of the source element. In summary this leads to a temperature at the surface of the source element higher than the temperature of the bulk of the source element, and thereby to an actual flux of evaporated and/or sublimated source material at least closer to the desired flux, preferably essentially equal to the desired flux.

The other way around, if the actual heat energy is higher than the nominal heat energy, the temperature of the bulk of the source element, and thereby in most of the cases also the temperature of the surface of the source element, is higher than needed for the desired flux of evaporated and/or sublimated source material, leading to an actual flux higher than the desired flux. Therefore, it is taken into account how low the working intensity can be set with respect to the nominal intensity for reaching again the thermal equilibrium and simultaneously ensuring an evaporation and/or sublimation of source material with the desired intensity, both as fast as possible. A reduction of the heat energy of the source element is for instance provided by radiative cooling. Especially for high temperatures of the source element as often present in TLE systems, this is an effective way of cooling, as said radiative cooling is proportional to the actual temperature to the fourth power.

In the final step f) of the method according to the present invention, the laser beam is provided with the working intensity determined in step e). Following the description above, the working intensity of the laser beam is determined such that changes in the desired flux, both increases and decreases, respectively, can be considered in a fast and effective way. In particular increases between desired fluxes, even starting from zero, can be provided by the method according to the present invention faster than simply turning on the laser source with the stationary power. Also changes between desired fluxes with non-zero value, in particular both increases and decreases, can be provided by the method according to the present invention in a fast and reliable way, especially faster than simply ramping the laser source to the next desired intensity. Thereby a flux of evaporated and/or sublimated source material can be adjusted in a controlled and arbitrary manner. In particular, the provided flux of evaporated and/or sublimated source material rises to a desired flux level immediately or at least after a short time, and/or decreases to a desired flux level immediately or at least after a short time.

Further, the method according to the present invention can comprise that in step a) a desired flux temperature of a surface of the source element corresponding to the desired flux is determined, and wherein in step e) if the actual heat energy is smaller than the nominal heat energy the working intensity is set to a value higher than the nominal intensity such that the desired flux temperature is reached at the surface of the source element. As already described above, the actual flux of source material evaporated and/or sublimated from the surface of the source element by the impinging laser depends on the actual temperature of the surface of the source element. In other words, if the nominal heat energy is stored in the source element, the desired flux temperature corresponds to the temperature of the bulk and in particular also of the surface of the source element. In the case that the actual heat energy is smaller than the nominal heat energy, said desired flux temperature is higher than the temperature corresponding to the actual heat energy. By determining the working intensity such that the surface of the source element comprises said desired flux temperature determined in step a), it can be ensured that also the actual flux of evaporated and/or sublimated source material matches the desired flux. As a result, this leads to a strongly nonuniform character of the heating of the source element, whereby the local temperature at the surface of the source element can be much higher than for the rest, in particular the bulk, of the source element, both in time, and in space, respectively.

According to an enhancement of the method according to the present invention, an actual temperature of the surface of the source element is measured, and in step e) the actual temperature is compared to the desired flux temperature, preferably in a closed loop control. Due to the already described linkage between surface temperature and flux of evaporated and/or sublimated source material, measuring the actual temperature of the surface of the source element provides an effective way of monitoring the actual flux of evaporated and/or sublimated source material. Said measurement can be provided by suitable temperature sensors such as for instance pyrometers. By comparing the measured actual temperature and the desired flux temperature, deviations of the actual flux from the desired flux can be identified. If the measured temperature is lower than the desired flux temperature, the working intensity determined in step e) will be increased, and vice versa. An implementation of said comparison in a closed loop control can provide a stable flux of evaporated and/or sublimated source material with the desired flux, in particular over an extended period of time.

Additionally, the method according to the present invention can be characterized in that in step d) the actual heat energy is determined by calculation taking into account one or more, preferably all, of the following properties:
Initial heat energy stored in the source element
Mass of the source element
Heat capacity of the source material
Heat conductivity of the source material
Total laser energy already irradiated onto the source element

This list is not complete and can be expanded by further properties which might influence the actual heat energy stored in the source element. The initial heat energy provides a starting point of the calculation. The total laser energy already impinged onto the source element allows deducing the amount of heat energy already absorbed by the source element. By taking into account the mass, heat capacity and/or heat conductivity of the source element, a response of the source element on said absorbed energy provided by the laser beam can be inferred.

Alternatively, or additionally, the method can comprise that in step d) the actual heat energy is determined by comparison with experimental and/or simulation data. Said experimental and/or simulation data can be prepared in advance, and for instance be provided as, preferably electronically accessible, look-up tables. As a result, the actual execution of the method according to the invention can be made less computationally intensive and complex, since the computationally intensive calculations are already carried out in advance.

Further, the method according to the present invention can be characterized in that at least the steps d) to f), preferably the steps a) to f), are carried out repeatedly, preferably in a closed loop control. Repeatedly in the sense of the present invention encompasses repetition rates of 100 mHz or lower, up to 10 MHz or higher. In other words, during the evaporation or sublimation process in particular the repeated or even continuous determination of the actual heat energy (step d)) and based on that the determination of the working intensity (step e)) is provided. By this, changes in the actual heat energy stored in the source element can be promptly considered. This allows also a provision of the laser beam with said updated, and if necessary adjusted, working intensity (step f)). Consequently, this provides that the desired flux of the evaporated or sublimated source material can be adjusted repeatedly. An implementation of said repetition in a closed loop control, especially based on the repeatedly determined actual heat energy stored in the source element, can provide a stable flux of evaporated and/or sublimated source material with the desired flux, in particular over an extended period of time.

Also, the method according to the present invention can comprise in step e) that the working intensity is determined such that a difference between the working intensity and the nominal intensity depends on a difference between the actual heat energy and the nominal heat energy, or that a ratio between working intensity and the nominal intensity depends on a ratio between the actual heat energy and the nominal heat energy. The higher the deviation of the actual heat energy stored in the source element from the nominal heat energy, the more energy of the impinging laser beam will be used for heating the bulk of the source element, if the nominal heat energy is higher than the actual heat energy, and the more the energy of the laser beam impinging on the source element will hinder the decrease of the actual heat energy, if the actual heat energy is higher than the nominal heat energy, respectively. Both the difference and the ratio of the deviation are variables representing the quantity of said deviation, by which said correlation can be taken into account. Thereby a higher or lower, respectively, deviation of actual heat energy and nominal heat energy leads to a more or less, respectively, pronounced deviation of working intensity and nominal intensity. Hence, reaching the aforementioned thermal equilibrium can be provided faster.

For instance, at a start of an evaporation and/or sublimation process immediately after turning on the laser beam, the deviation of actual heat energy and nominal heat energy will be at maximum, and so will be the deviation of determined working intensity and nominal intensity. After a while, the bulk of the source element will have absorbed some of the laser energy and hence has heated up, the actual heat energy will have risen and hence its deviation to the nominal heat energy will be lower. Therefore, also the deviation of the working intensity from the nominal intensity can likewise be decreased. Eventually, for a constant desired flux the working intensity ideally converges to the nominal intensity.

Additionally, the method according to the present invention can be enhanced by that the working intensity is set to a maximum intensity of the laser beam if the actual heat energy is smaller than the nominal heat energy and the deviation exceeds a first threshold, and/or wherein the working intensity is set to a minimum intensity of the laser beam, preferably to zero, if the actual heat energy is higher than the nominal heat energy and the deviation exceeds a second threshold. The laser source cannot provide a laser beam with a higher intensity than its maximum intensity, and likewise cannot provide a laser beam with a lower intensity than its minimum intensity or even zero, respectively.

In particular for determinations of the working intensity depending on said deviation, it is possible that the deviation is so large that said dependence would lead to working intensities determined in step e) of the method according to the present invention, both high and low, respectively, which cannot be provided by the laser source. The first and second threshold, respectively, preferably are chosen such that said particularly large deviations can be identified and at least partly met by providing the laser beam with its maximum or minimum intensity, respectively. Hence, also for particularly large deviations of the actual heat energy and the nominal heat energy an execution of the method according to the present invention can be ensured without risking the structural integrity of the laser source by setting the working intensity to values that cannot be provided.

According to another enhanced embodiment of the method according to the present invention, the difference between working intensity and the nominal intensity is proportional to the difference between the actual heat energy and the nominal heat energy, or wherein the ratio between working intensity and the nominal intensity is proportional to the ratio between the actual heat energy and the nominal heat energy. Proportionality is a very simple mathematical relationship between two values, present the difference or the ratio of the actual heat energy and the nominal heat energy, and the working intensity and the nominal intensity, respectively. In addition, proportional relationships can be easily implemented in control algorithms. Hence, by using proportionality for said relationship, the method according to the present invention can be simplified.

Further, the method according to the present invention can comprise that in step e) a deviation of the actual heat energy from the nominal heat energy is determined if the actual heat energy differs from the nominal heat energy by more than 10%, in particular more than 1%, preferably more than 0.1%. In other words, according to this embodiment a presence of said deviation is only determined if the actual heat energy comprises a value located outside a range around the nominal heat energy.

Without said range, each determined deviation, even if very small, leads to a change in the determined working intensity. In particular in later stages of the evaporation and/or sublimation process, at which the thermal equilibrium of the source element is at least almost reached and hence the working intensity is at least close to the nominal intensity, this can lead to unwanted oscillations of the determined working intensity around the nominal intensity, and hence of the actually provided flux of evaporated and/or sublimated source material around the desired flux. By implementing the aforementioned range, within which no deviation is determined, said unwanted oscillations can be avoided.

The method can also be characterized in that the desired flux is determined for a period of time and/or comprises a time dependence. In other word, the desired flux can comprise a starting point in time and an end point in time. By that, for instance an integral value of the provided flux of evaporated and/or sublimated source material can be set. Additionally, said period in time can also be fragmented, in other words the desired flux can be determined with active time periods with breaks in between. Additionally, or alternatively, a time dependence of the determined desired flux in the sense of the present invention includes also possible changes of a value of the flux itself during said active time periods, for instance increases and/or decreases of the flux. A wide variety of possible determined desired fluxes can thereby be provided.

According to an enhanced embodiment of the method, the desired flux determined in step a) comprises one or more constant sections. Constant fluxes of evaporated and/or sublimated source material are often required for coating processes, in particular due to purity reasons and since this can support uniform growth of coating layers. By providing determined fluxes with one or more constant sections, said constant fluxes can also be provided by implementing the method according to the present invention.

The method according to the present invention can be enhanced further by that the desired flux at least comprises two sections with constant desired flux, wherein the respective desired fluxes differ by a factor of 2 or more, in particular by a factor of 10 or more, preferably by a factor of 100 or more, whereby preferably said two sections are adjunct and/or subsequent. As already described above, the actually provided flux of evaporated and/or sublimated source material strongly depends on the laser power and hence on the desired intensity and working intensity, respectively. In particular, by changing the intensity of the provided laser beam, vast flux variations can be provided on a very short time scale. As the abundance of evaporated and/or sublimated source material arriving at the substrate influences the surface mobility on the substrate, this can be for instance used for controlling growth kinetics. Adjunct and/or subsequent sections in the sense of the present invention generally enclose sections which immediately follow each other. However, also sections which follow each other with a short transitional section are considered as adjunct and/or subsequent, if said section is negligible with respect to the duration of the two respective sections with constant desired flux.

According to a further enhancement, the method according to the present invention can comprise that the desired flux determined in step a) comprises one or more increasing and/or decreasing sections, in particular linearly increasing and/or linearly decreasing sections. For some applications, also an increasing and/or decreasing flux of evaporated and/or sublimated source material can be suitable. According to the present invention, variations in flux are provided by variations of the working intensity, which can be realized on very short time scales in the order of microseconds or even faster. As the steps a) to f) preferably are carried out repeatedly, this not only applies for a transition between sections with constant desired fluxes of different value, but furthermore analogously also for sections with increasing and/or decreasing desired fluxes, in particular with linearly increasing and/or linearly decreasing desired fluxes.

In a further enhanced embodiment of the method according to the present invention, the desired flux determined in step a) comprises a repetitive pattern of a section with constant desired flux during a first time period and a section with no desired flux in a subsequent second time period, wherein the first time period and the second time period are chosen such that the nominal heat energy is not reached during evaporation and/or sublimation of the source material. Providing the evaporated and/or sublimated source material with a continuous desired flux leads in the long run to a source element storing the nominal heat energy. Hence, the source element, in particular its surface, continuously comprises the desired flux temperature corresponding to said nominal heat. However, this inevitably leads to an often non neglectable parasitic heating of the surrounding of the source element, for instance due to radiative cooling of the source element. However, this can be harmful for the other elements of the TLE system, in particular for the substrate.

By determining the desired flux as the repetitive pattern as described above, these negative parasitic heating of the environment by the source element can be drastically reduced.

As advantage of the method according to the present invention, the constant desired flux during the first time period can be provided almost immediately at the beginning of each period. However, the source element provides only at the surface the desired flux temperature corresponding to said desired flux, the bulk of the source element remains at a lower temperature. During the second time period, the temperature of the source element equalizes without any further heating by the laser beam, still at a temperature value well below the desired flux temperature. Then, this procedure repeats. In summary, the mean temperature of the source element continuously stays well below the desired flux temperature. Thereby, the overall effects of parasitic heating can be reduced at the expense of the time needed to provide an appropriate total amount of flux of evaporated and/or sublimated source material.

Further, the method according to the present invention can also be enhanced by that a mean of the actual heat energy is smaller than 0.5 times the nominal heat energy, in particular smaller than 0.25 times the nominal heat energy during the first time periods. Said mean heat energy directly defines the mean temperature of the source element, in particular of the surface of the source element. As the radiative cooling scales with the fourth power of the temperature, reducing a mean of the actual heat energy to half or even to a quarter of the nominal heat energy reduces the effects of parasitic heating even more drastically.

Additionally, the method according to the present invention can be characterized in that the source comprises cooling means, and wherein the method comprises active cooling of the source element by the cooling means during evaporation and/or sublimation of the source material. Said cooling means can for instance comprise cooling ducts within a cooling body thermally attached to the source element, whereby a coolant fluid, for instant water or liquid nitrogen, flows through said cooling ducts. As already mentioned above, if the actual heat energy is higher than the nominal heat energy, the bulk of the source element normally comprises a temperature which is higher than a temperature corresponding to the desired flux. Hence, the source element has to cool down for losing at least part of said stored heat energy. By providing cooling means, said cooling can be enhanced and accelerated, in particular compared with radiative cooling only.

In an enhanced embodiment of the method according to the present invention, the source element is actively cooled continuously by the cooling means. In other words, the cooling means are running continuously and especially are not repeatedly turned on and off. Thereby, the execution of the method according to the present invention and especially the TLE system constructed to carry out the method according to the present invention can be simplified.

Further, the method according to the present invention can be enhanced by that the active cooling of the source element by the cooling means is considered while determining the nominal intensity in step c). The active cooling of the source element by the cooling means, especially if said cooling is provided continuously, carries away thermal energy ultimately provided by the impinging laser beam. “Considering said active cooling” in the sense of the present invention especially means that the working intensity is determined such that a surplus of intensity is added for compensation of the active cooling. Thereby, the positive effects of said cooling, especially a faster response of the actual flux to reductions in the desired flux, can be provided simultaneously to the overall advantage of the method according to the present invention of a fast, especially almost immediate, response to increases of the desired flux, in particular at turning-on phases of the evaporation and/or sublimation process.

Further, the method according to the present invention can comprise that the TLE system comprises two or more sources, wherein each source comprises a source element consisting of a source material, and wherein for evaporation and/or sublimation of the respective source material steps a) to f) are performed for each of the source materials, respectively. In other words, in said TLE system more than one source material can be evaporated and/or sublimated, and said evaporation and/or sublimation process can be performed using the present method according to the present invention. Said evaporation and/or sublimation processes of the different source materials can be performed at the same or at separate times. Hence, for each source material, a flux of said evaporated and/or sublimated source material can be adjusted in a controlled and arbitrary manner. In particular, the respectively provided flux of evaporated and/or sublimated source material rises to a desired flux level immediately or at least after a short time, and/or decreases to a desired flux level immediately or at least after a short time.

In addition, the method according to the present invention can be further enhanced by that the desired flux determined in step a) carried out for a first source material is higher than the desired flux determined in step a) carried out for a second source material, whereby the respective step e) is carried out simultaneously for both source materials. By implementing this embodiment of the method according to the present invention, it can be provided that the first source material is present at the surface of the substrate to be coated in a greater abundancy than the second source material. This can be used for example for ensuring a certain stoichiometric ratio two source materials on the substrate surface.

It is noted that the enhancement described in the previous paragraph is not limited to two source materials, but can be analogously implemented for three or more source materials. In particular, the method according to the present invention can also comprise that step a) is carried out for three or more source materials for determining the respective desired flux for each of said three or more source materials, whereby the respective step e) is carried out simultaneously for all three or more source materials. Hence, also a desired certain stoichiometric ratio of three or more source materials on the substrate surface can be provided.

The embodiment described in the previous paragraph is not limited to two source materials and can accordingly be implemented to three or more source materials simultaneously and/or subsequently evaporated and/or sublimated in the same TLE system.

According to a second aspect of the present invention, the object is satisfied by a thermal laser evaporation (TLE) system, the TLE system comprising a reaction chamber fillable with a reaction atmosphere, a substrate arranged in the reaction chamber, one or more sources arranged in the reaction chamber, each source comprising a source element consisting of a source material, and a laser source for providing a laser beam impinging on the source element and thereby evaporating or sublimating the source material for providing a flux of evaporated or sublimated source material for a deposition onto the substrate. The TLE system according to the second aspect of the present invention is constructed to carry out the method according to the first aspect of the present invention. By that, the thermal laser evaporation system according to the second aspect of the present invention provides all features and advantages described above with respect to a method according to the first aspect of the present invention.

The invention will be explained in detail in the following by means of embodiments and with reference to the drawings. In particular, in the figures are shown:

FIG. 1A schematic view of a TLE system according to the state of the art with a shutter,

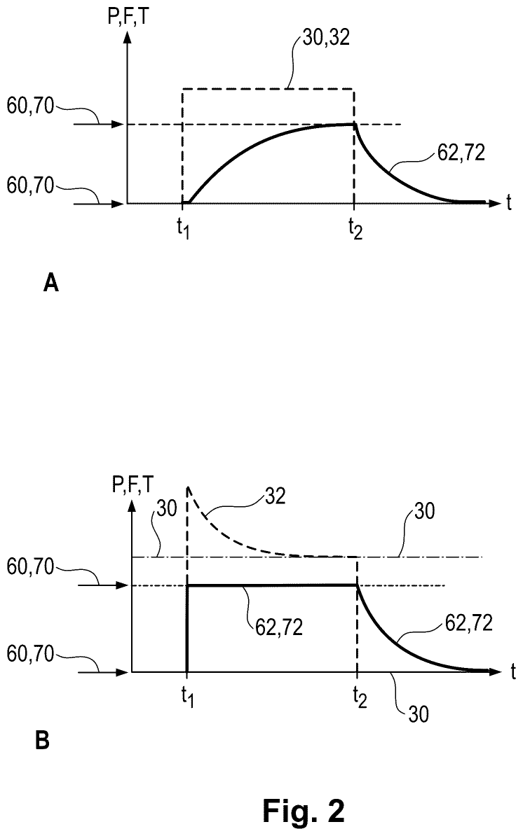

FIG. 2 Diagrams of power, flux and source temperature versus time for a preparatory stage and for a first embodiment of the method according to the present invention,

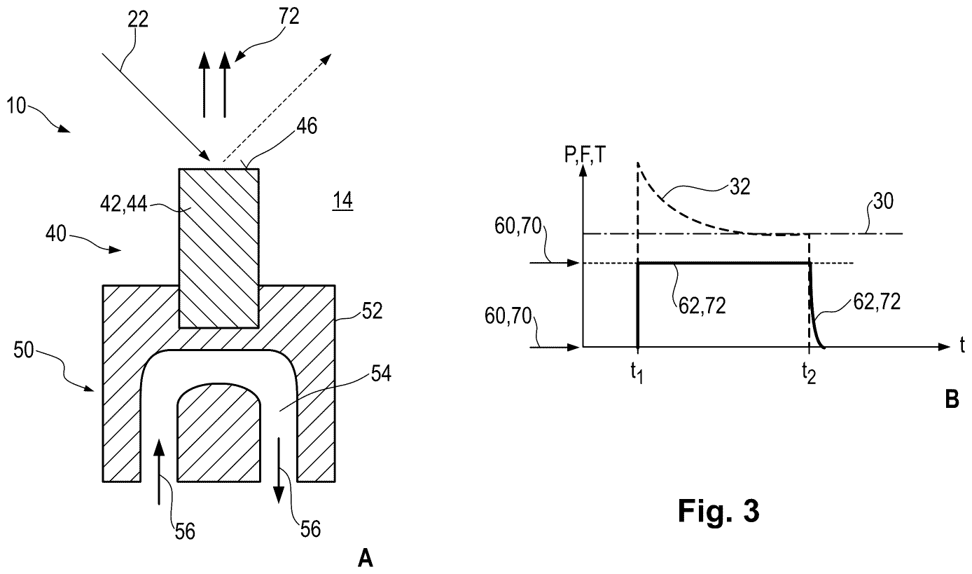

FIG. 3 Cooling means and a diagram of power, flux and source temperature versus time for a second embodiment of the method according to the present invention,

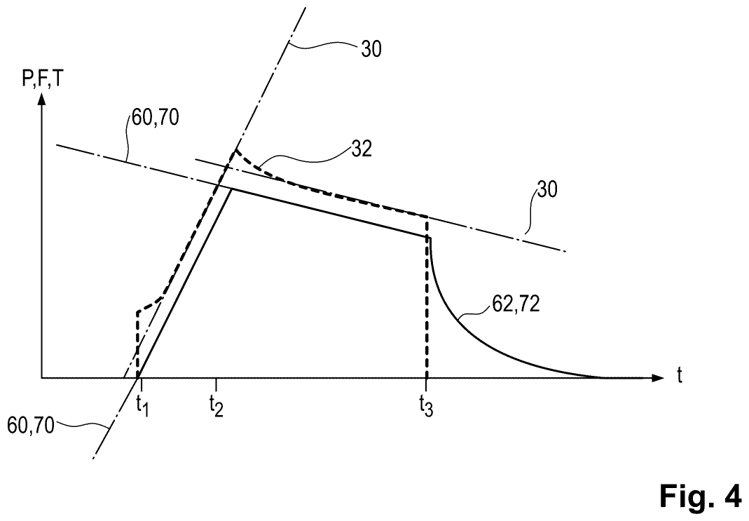

FIG. 4A diagram of power, flux and source temperature versus time for a third embodiment of the method according to the present invention,

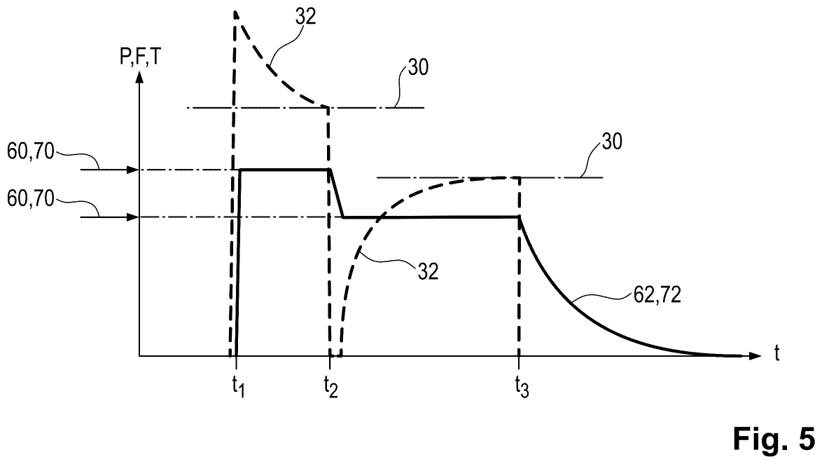

FIG. 5A diagram of power, flux and source temperature versus time for a forth embodiment of the method according to the present invention,

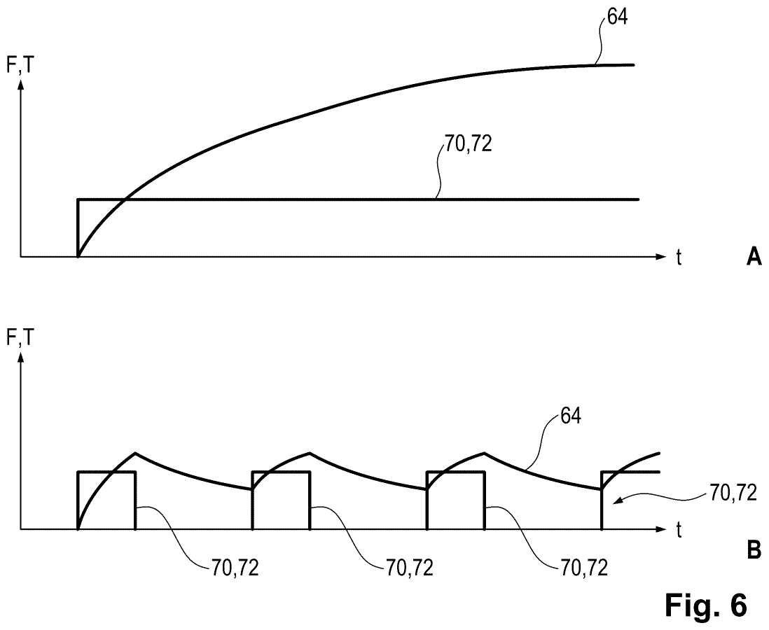

FIG. 6 Diagrams of flux and substrate temperature versus time for two different embodiments of the method according to the present invention, and

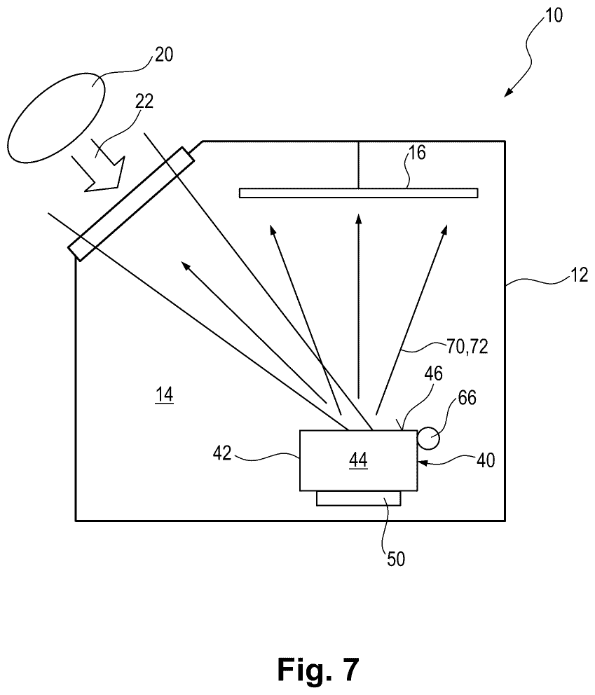

FIG. 7A schematic view of a thermal laser evaporation system according to the present invention.

In the following FIGS. 2 to 5, several diagrams are shown schematically depicting the properties laser power (denoted as “P”), and hence laser intensity 30, 32, desired and actual flux 70, 72 (denoted as “F”) of evaporated and/or sublimated source material 44 and source temperature 60, 62 (denoted as “T”), especially a surface temperature 62, versus time (denoted as “t”).

It should be noted that in FIGS. 2 to 5, fluxes 70, 72 and temperatures 60, 62 are represented by the same line to simplify the plots. In fact, the depicted lines are diagrams of the fluxes 70, 72, Due to the approximately Arrhenius-type dependence of fluxes 70, 72 from temperature 60, 62, especially from the surface temperature 62, the respective diagrams of the temperatures 60, 62 would show slightly different curves, in particular with less pronounced changes. In particular, due to the aforementioned Arrhenius-type dependence, there is no general proportional dependency between fluxes 70, 72 and temperatures 60, 62.

Further, all diagrams of FIGS. 2 to 5 and also of FIG. 6 are described for a single source element 42 (see FIG. 7 for an image of a respective TLE system 10 and its elements). However, the described embodiments of the method according to the present invention are also applicable to TLE systems 10 comprising two or more sources 40, whereby the evaporation and/or sublimation processes for the two or more sources 40 can be simultaneously and/or subsequently carried out, whereby for each of the processes the method according to the invention is carried out adapted to the specific evaporation and/or sublimation process.

In the following, for all mentioned elements of the TLE system 10 not depicted in FIGS. 2 to 6, please see FIG. 7.

FIG. 2 shows in subfigure A said diagram for a preparatory stage and in subfigure B for an actual embodiment of the method according to the present invention. Both diagrams show an evaporation and/or sublimation process with a desired flux 70, whereas the desired flux 70 should be provided starting from a first point in time t₁ and ending at a second point in time t₂. Please note that the desired flux 70 corresponds to the desired flux temperature 60 with the usual Arrhenius-type dependence of the vapor pressure.

For the preparatory stage depicted in subfigure A, the laser source 20 provides a constant working intensity 32 corresponding to the nominal intensity 30 and is simply switched on at t₁ and again turned off at t₂. This is depicted by the rectangular shape of the nominal and working intensity 30, 32, respectively. However, at t₁ a bulk of the source element 42 comprises a temperature well below the desired flux temperature 60. Hence, a not negligible part of the energy of the impinging laser beam 22 is used for heating up the source element 42. Effectively, this leads to the slowly rising curve of the actual temperature 62 and hence of the actual provided actual flux 72 as shown in subfigure A of FIG. 2.

In contrast to that, subfigure B of FIG. 2 depicts a similar diagram, but now of an evaporation and/or sublimation process provided by a first embodiment of the method according to the present invention. Similar to subfigure A, a desired flux 70 represented by the desired flux temperature 60 is set in a first step a) of the method according to the present invention, which should be met by the actual flux 72. Please note that after t₂ the desired flux temperature 60 drops to zero. As depicted, the desired flux 70 can comprise or consist of a section of constant value.

Additionally, in the following step b) a nominal heat energy is determined, which corresponds to said desired flux 70 such that the source element 42 stores said nominal heat energy, if the mean temperature of the source element 42 is the desired flux temperature 60.

Further, in the following step c) a nominal intensity 30 is determined, which again corresponds to the desired flux 70 and the nominal heat energy. In particular, the nominal intensity 30 is the specific laser beam 22 intensity needed for providing the desired flux 70 if the source element 42 stores the nominal heat energy.

The next two steps d) and e) are the main differences to simply turning on the laser beam 22 as depicted in subfigure A. First of all, in step d) an actual heat energy stored in the source element 42 is determined. In other words, after step d) information is present how much the source element 42 is already heated up during the ongoing evaporation and/or sublimation process.

This information is used in the subsequent step e), in which the actual heat energy is compared to the nominal heat energy. Thereby, a deviation of these values can be determined.

If the nominal heat energy is larger than the actual heat energy, energy of the laser beam 22 will be at least partly used for heating up of the bulk of the source element 42 and not for evaporating and/or sublimating source material 42, and vice versa. This finding is used to determining a working intensity 32, which will be higher than the nominal intensity 30 in the first case and lower in the latter case. For avoiding unwanted oscillations of the determined working intensity 32, it can be foreseen that said deviation of the actual heat energy from the nominal heat energy is determined only if the values of said heat energies differ by more than 10%, in particular more than 1%, preferably more than 0.1%.

In the last step f) of the method according to the present invention, the laser beam 22 is provided with the working intensity 32 determined in the previous step e).

As a result, as long as the actual heat energy stored in the source element 42 falls short of the nominal heat energy, the working intensity 32 is determined with a higher value for compensating the energy loss due to heating up of the source element 42. Thereby, the actual temperature 62 at the emitting surface 46 of the source element 42 can be decoupled from the actual heat energy. As the actual flux 72 originating from the source element 42 is strongly linked to the actual temperature 62 of the emitting surface 46, this allows, as depicted in subfigure B, providing the actual flux 72 corresponding to the desired flux 70 almost immediately after t₁ without needing a shutter 80.

After t₂ the desired flux 70 is set to zero. Hence, the actual heat energy stored in the source element 42 is suddenly larger than the nominal heat energy determined in step b) of the method according to the present invention. Hence, the working intensity 32 is also determined as low as possible, namely also zero. The actual heat energy stored in the source element 42 hence also drops, in the embodiment of FIG. 2 mainly due to radiative cooling. Especially for high temperatures of the source element 42 as often present in TLE systems 10, this is an effective way of cooling, as said radiative cooling is proportional to the fourth power of the actual temperature 62 at the surface 46 of the source element 42. Thereby also the actual temperature 62 of the surface 46 gets lower and lower very fast, and quickly the actual flux 72 reaches the desired flux 70 and ceases.

Preferably, the desired flux temperature 60 is determined together with the desired flux 70. As already mentioned, the actual flux 72 originating from the source element 42 is strongly linked to the actual temperature 62 of the emitting surface 46 of the source element 42. Hence, in step e) the working intensity 32 is preferably determined such that said desired flux temperature 60 is reached at said surface 46. For an actual control, in particular a closed-loop control, said actual temperature 62 can be measured by suitable temperature sensors 66 and a comparison of the measured actual temperature 62 with the desired flux temperature 60 can be considered when determining the working intensity 32 in step e) of the method according to the present invention.

Overall, it is advantageous, if said steps a) to f), or at least steps d) to f), of the method according to the present invention are repeatedly carried out. Additionally, or alternatively, to the aforementioned closed-loop control based on the temperature 60, 62, also a closed loop-control based on the heat energy stored in the source element 42 is possible. In particular, said actual heat energy stored by the bulk of the source element 42 can be determined by calculations taking into account properties of the source element 42 of the corresponding setup and/or of the ongoing evaporation and/or sublimation process, and/or be determined by comparison with experimental and/or simulation data.

For reaching the nominal heat energy as fast as possible, it is preferred that the deviation of the nominal heat energy from the actual heat energy is considered during the determination of the working intensity 32. In general, a larger deviation of the heat energies leads to a larger deviation of the working intensity 32 from the nominal intensity 30. For considering said deviation, for instance a difference or a ratio, respectively, of the actual heat energy and the nominal heat energy can be used as basis for a determination of a difference or a ratio, respectively, of the working intensity 32 and the nominal intensity 30. For instance, said differences or ratios can be proportionally linked with each other.

This procedure is for instance clearly visible in subfigure B. At t₁, the actual heat energy stored in the source element 42 is minimal, and hence the deviation between actual heat energy and nominal heat energy is large. Therefore, also the deviation of the determined working intensity 32 from the nominal intensity 30 comprises its largest value at the beginning of the evaporation and/or sublimation process. If the deviation exceeds a threshold, a maximum intensity providable by the laser source 20 can also be set as working intensity 32 for avoiding harming the laser source 20. Towards t₂, the source element 42 heats up and hence the actual heat energy stored in the source element 42 approaches more and more the nominal heat energy. This behavior is also transferred to the determined working intensity 32, which converges towards the nominal intensity 30.

As mentioned with respect to subfigure B of FIG. 2, at a sudden drop of the desired flux 70 to zero, the actual heat energy stored in the source element 42 has to be carried away. FIG. 3 shows a preferred enhancement, in which the source element 42 is cooled not only by radiative cooling, but also by a dedicated cooling means 50.

Subfigure A depicts a schematic image of a source 40 comprising a source element 42 and said cooling means 50. The bulk of the source element 42 consisting of source material 44 is thermally coupled with a body 52 of the cooling means 50. Within the body 52, cooling ducts 54 are arranged for a flow of coolant fluid 56, for instance water or liquid nitrogen. Preferably, the cooling means 50 work continuously, in other words the source element 42 is cooled at all times.

In subfigure B, a diagram of an evaporation and/or sublimation process similar to subfigure B of FIG. 2 is shown. As difference, the source 40 used for the depicted evaporation and/or sublimation process is equipped with a cooling means 50. As the cooling means 50 preferably cools the source element 42 in a continuous way, said cooling preferably is considered when determining the working intensity 32, as the additionally energy loss due to the cooling has to be compensated. This is done in FIG. 3, as the actual flux 72 again reaches the desired flux 70 almost immediately after t₁. Again, the desired flux 70 corresponds to the desired flux temperature 60. For the remaining general features of the method according to the present invention also shown in subfigure B of FIG. 3, please refer to the respective description above with respect to subfigure B of FIG. 2.

The main advantage of the implementation of the cooling means 50 is visible after t₂, whereby at this point in time the desired flux 70 again drops to zero. As the cooling means 50 cools the source element 42 in a more efficient way as solely by radiative cooling, in particular starting from lower actual temperatures 62, the actual heat energy reaches the nominal heat energy faster and hence the actual temperature 62 of the surface 46 also drops to the desired flux temperature 60 more quickly. As result, also turning off the provided actual flux 72 can be provided in an almost immediate way, in particular without a shutter 80.

As depicted in FIGS. 2, 3, the desired flux 70 can comprise sections with constant values for the desired flux 70. However, as the response time of the normally used laser sources 20 is in the order of microseconds, the method according to the present invention is not limited to said constant desired fluxes 70.

As depicted in FIG. 4, also sections with, in particular linearly, increasing and/or decreasing values determined as desired fluxes 70 are possible, namely linearly increasing between t₁ and t₂, and linearly decreasing between t₂ and t₃. The nominal intensities 30 and in particular also the working intensities 32 are accordingly determined during execution of the method according to the present invention, and hence the actual temperature 62 and thereby also the actual flux 72 almost immediately follow the desired flux temperature 60 and the desired flux 70, respectively. Again, the desired flux 70 corresponds to the desired flux temperature 60.

In FIG. 5, a diagram of a more complex evaporation and/or sublimation process is shown. After an initial constant section of desired flux 70 between t₁ and t₂ follows a second constant section of desired flux 70 between t₂ and t₃ with a lower value of the desired flux 70. Again, the desired flux 70 corresponds to the desired flux temperature 60.

Again, the determined working intensity 32 compensates the deviation of the actual heat energy stored in the source element 42 from the nominal heat energy determined during the execution of the method according to the present invention. At the beginning at t₁, the source element 42 is relatively cool and has to be heated up. Consequently, the determined working intensity 32 is highest at the beginning and converges to the first value of the nominal intensity 30 towards t₂.

After t₂, the desired flux 70 drops to its lower new value. Hence, the actual heat energy stored in the source element 42 is higher than the nominal heat energy. Consequently, the value of the working intensity 32 is determined as zero, thereby allowing the source element 42 to cool down. As the desired flux temperature 62 is reached shortly afterwards at the surface 46 of the source element 42, the determined value of the working intensity 32 starts rising again, converging towards the new value of the nominal intensity 30. After t₃, the desired flux 70 drops to zero, which also causes the working intensity 32 to be determined as zero. Due to not perfect cooling of the source element 42, the actual drop of the actual temperature 62 and hence of the actual flux 72 is somewhat delayed.

Please note that the depicted difference of the two values of the constant desired fluxes 70 is for illustration only. By implementing the method according to the present invention, said values of desired fluxes 70 can differ by a factor of 2 or more, in particular by a factor of 10 or more, preferably by a factor of 100 or more.

FIG. 6 illustrates another advantageous use of the method according to the present invention, namely avoiding parasitic heating in particular of the substrate 16. The two subfigures A, B depict diagrams of fluxes 70, 72 and additionally the substrate temperature 64 versus time. The actual flux 72, in particular its fast convergence towards the desired flux 70, is provided by using the method according to the present invention as described above.

In subfigure A, the desired flux 70 and hence the actual flux 72 is provided as continuous flux 70, 72 with a constant value. Consequently, the source element is heated up until it stores the nominal heat energy and the actual temperature 62 is equal to the desired flux temperature 60 (temperatures 60, 62 of the source element 42 not depicted). However, during all times radiative cooling of the source element 42 is active, resulting in slowly heating up the substrate 16, as visible in the rising substrate temperature 64. Unfortunately, high substrate temperatures 64 can be harmful, not only for the coating process, but in the worst case also for a structural integrity of the substrate 16.

Subfigure B depicts a possible solution for said problem of parasitic heating, provided by the method according to the present invention. As described above, by implementing the method according to the present invention almost immediately turning on and off an actual flux 72 of evaporated and/or sublimated source material 44 can be provided, in particular without shutters 80. Hence, in this case the desired flux 70, and therefore at least essentially also the actual flux 72, comprises a repetitive pattern of sections with constant flux 70, 72 and sections with no flux 70, 72. The time periods of said sections are chosen such that the nominal heat energy is never reached by the actual heat energy. In fact, it is preferred that a mean of the actual heat energy is smaller than 0.5 times the nominal heat energy, in particular smaller than 0.25 times the nominal heat energy. Nevertheless, the desired flux 70 can be provided, as the working intensity 32 (not depicted) is accordingly determined. As visible in subfigure B, there still remains some parasitic heating of the substrate 16, but the substrate temperature 64 oscillates around a significantly lower value. Harmful effects of said parasitic heating can thereby be avoided.

FIG. 8 shows a schematic and simplified cross sectional side view of a thermal laser evaporation (TLE) system 10 according to the present invention. The TLE system 10 is constructed to carry out the method according to the present invention. Within a reaction chamber 12, a source 40 providing a source element 42 comprising a source material 44 and a substrate 16 are arranged. Further, a cooling means 50 is present for actively cooling the source element 42. A temperature sensor 66 is used for measuring an actual temperature 62 (see FIGS. 2 to 5) of the source element 42. The reaction chamber 12 is filled with a reaction atmosphere 14, for instance a vacuum or a suitable reaction gas.

A laser beam 22 provided by a laser source 20 is coupled into the reaction chamber 10 for impinging onto the surface 46 of the source element 42. By implementing the method according to the present invention, for instance in one of the embodiments described above with respect to FIGS. 2 to 6, an actual flux 72 of evaporated and/or sublimated source material 44 can be adjusted in a controlled and arbitrary manner. In particular, the provided actual flux 72 of evaporated and/or sublimated source material 44 rises to a value of a desired flux 70 immediately or at least after a short time, and/or decreases to a value of a desired flux 70 immediately or at least after a short time.

LIST OF REFERENCES

| | |
|---|---|
| 10 | TLE system |
| 12 | Reaction chamber |
| 14 | Reaction atmosphere |
| 16 | Substrate |
| 18 | Aperture |
| 20 | Laser source |
| 22 | Laser beam |
| 30 | Nominal intensity |
| 32 | Working intensity |
| 40 | Source |
| 42 | Source element |
| 44 | Source material |
| 46 | Surface |
| 50 | Cooling means |
| 52 | Body |
| 54 | Coolant duct |
| 56 | Coolant fluid |
| 60 | Desired flux temperature |
| 62 | Actual temperature |
| 64 | Substrate temperature |
| 66 | Temperature sensor |
| 70 | Desired flux |
| 72 | Actual flux |
| 74 | Deposition flux |
| 80 | Shutter |

1-22. (canceled)

23. Method of using a thermal laser evaporation system, the TLE system comprising a reaction chamber fillable with a reaction atmosphere, a substrate arranged in the reaction chamber, one or more sources arranged in the reaction chamber, each source comprising a source element consisting of a source material, and a laser source for providing a laser beam impinging on the source element and thereby evaporating or sublimating the source material for providing a flux of evaporated or sublimated source material for a deposition onto the substrate,
the method comprising the steps of
a) Determining a desired flux of source material evaporated and/or sublimated source material by the laser beam,
b) Determining a nominal heat energy stored in the source element corresponding to the desired flux,
c) Determining a nominal intensity of the laser beam corresponding to the desired flux when the source element stores the nominal heat energy,
d) Determining an actual heat energy stored in the source element,
e) Determining a working intensity of the laser beam in dependence of a deviation of the actual heat energy from the nominal heat energy, wherein
the working intensity is higher than the nominal intensity if the actual heat energy is smaller than the nominal heat energy, and
the working intensity is smaller than the nominal intensity if the actual heat energy is higher than the nominal heat energy, and
f) Providing the laser beam with the working intensity.

24. Method according to claim 23,
wherein in step a) a desired flux temperature of a surface of the source element corresponding to the desired flux is determined, and
wherein in step e) if the actual heat energy is smaller than the nominal heat energy the working intensity is set to a value higher than the nominal intensity such that the desired flux temperature is reached at the surface of the source element.

25. Method according to claim 24,
wherein an actual temperature of the surface of the source element is measured, and wherein in step e) the actual temperature is compared to the desired flux temperature.

26. Method according to claim 23,
wherein in step d) the actual heat energy is determined by calculation taking into account one or more or all of the following properties:
-Initial heat energy stored in the source element
Mass of the source element
Heat capacity of the source material
Heat conductivity of the source material
Total laser energy already irradiated onto the source element

27. Method according to claim 23,
wherein in step d) the actual heat energy is determined by comparison with experimental and/or simulation data.

28. Method according to claim 23,
wherein at least the steps d) to f), or the steps a) to f), are carried out repeatedly.

29. Method according to claim 23,
wherein in step e) the working intensity is determined such
that a difference between the working intensity and the nominal intensity depends on a difference between the actual heat energy and the nominal heat energy, or that a ratio between working intensity and the nominal intensity depends on a ratio between the actual heat energy and the nominal heat energy.

30. Method according to claim 29,
wherein the working intensity is set to a maximum intensity of the laser beam if the actual heat energy is smaller than the nominal heat energy and the deviation exceeds a first threshold, and/or
wherein the working intensity is set to a minimum intensity of the laser beam if the actual heat energy is higher than the nominal heat energy and the deviation exceeds a second threshold.

31. Method according to claim 29,
wherein the difference between working intensity and the nominal intensity is proportional to the difference between the actual heat energy and the nominal heat energy, or
wherein the ratio between working intensity and the nominal intensity is proportional to the ratio between the actual heat energy and the nominal heat energy.

32. Method according to claim 23,
wherein in step e) a deviation of the actual heat energy from the nominal heat energy is determined if the actual heat energy differs from the nominal heat energy by more than 10%.

33. Method according to claim 23,
wherein the desired flux is determined for a period of time and/or comprises a time dependence.

34. Method according to claim 33,
wherein the desired flux determined in step a) comprises one or more constant sections.

35. Method according to claim 34,
wherein the desired flux at least comprises two sections with constant desired flux, wherein the respective desired fluxes differ by a factor of 2 or more.

36. Method according to claim 33,
wherein the desired flux determined in step a) comprises one or more increasing and/or decreasing sections.

37. Method according to claim 33,
wherein the desired flux determined in step a) comprises a repetitive pattern of a section with constant desired flux during a first time period and a section with no desired flux in a subsequent second time period, wherein the first time period and the second time period are chosen such that the nominal heat energy is not reached during evaporation and/or sublimation of the source material.

38. Method according to claim 37,
wherein a mean of the actual heat energy is smaller than 0.5 times the nominal heat energy.

39. Method according to claim 23,
wherein the source comprises cooling means, and wherein the method comprises active cooling of the source element by the cooling means during evaporation and/or sublimation of the source material.

40. Method according to claim 39,
wherein the source element is actively cooled continuously by the cooling means.

41. Method according to claim 39,
wherein the active cooling of the source element by the cooling means is considered while determining the nominal intensity in step c).

42. Method according to claim 23,
wherein the TLE system comprises two or more sources, wherein each source comprises a source element consisting of a source material, and wherein for evaporation and/or sublimation of the respective source material steps a) to f) are performed for each of the source materials, respectively.

43. Method according to claim 42,
wherein the desired flux determined in step a) carried out for a first source material is higher than the desired flux determined in step a) carried out for a second source material, whereby the respective step f) is carried out simultaneously for both source materials.

44. Thermal laser evaporation system, the TLE system comprising a reaction chamber fillable with a reaction atmosphere, a substrate arranged in the reaction chamber, one or more sources arranged in the reaction chamber, each source comprising a source element consisting of a source material, and a laser source for providing a laser beam impinging on the source element and thereby evaporating or sublimating the source material for providing a flux of evaporated or sublimated source material for a deposition onto the substrate,
wherein the TLE system is constructed to carry out a method of using the thermal laser evaporation system, the TLE system comprising a reaction chamber fillable with a reaction atmosphere, a substrate arranged in the reaction chamber, one or more sources arranged in the reaction chamber, each source comprising a source element consisting of a source material, and a laser source for providing a laser beam impinging on the source element and thereby evaporating or sublimating the source material for providing a flux of evaporated or sublimated source material for a deposition onto the substrate,
the method comprising the steps of
a) Determining a desired flux of source material evaporated and/or sublimated source material by the laser beam,
b) Determining a nominal heat energy stored in the source element corresponding to the desired flux,
c) Determining a nominal intensity of the laser beam corresponding to the desired flux when the source element stores the nominal heat energy,
d) Determining an actual heat energy stored in the source element,
e) Determining a working intensity of the laser beam in dependence of a deviation of the actual heat energy from the nominal heat energy, wherein
the working intensity is higher than the nominal intensity if the actual heat energy is smaller than the nominal heat energy, and
the working intensity is smaller than the nominal intensity if the actual heat energy is higher than the nominal heat energy, and
f) Providing the laser beam with the working intensity.

45. Method according to claim 25,
wherein in step e) the actual temperature is compared to the desired flux temperature in a closed loop control.

46. Method according to claim 28,
wherein at least the steps d) to f), or the steps a) to f), are carried out repeatedly in a closed loop control.

47. Method according to claim 23,
wherein in step e) a deviation of the actual heat energy from the nominal heat energy is determined if the actual heat energy differs from the nominal heat energy by more than 1%.

48. Method according to claim 23,
wherein in step e) a deviation of the actual heat energy from the nominal heat energy is determined if the actual heat energy differs from the nominal heat energy by more than 0.1%.

49. Method according to claim 35,
wherein said two sections are adjunct and/or subsequent.

50. Method according to claim 36,
wherein the desired flux determined in step a) comprises one or more linearly increasing and/or linearly decreasing sections.

51. Method according to claim 38,
wherein a mean of the actual heat energy is smaller than 0.25 times the nominal heat energy during the first time periods.
